(19) United States
(12) Patent Application Publication
(10) Pub. No.: US 2025/0279279 A1
(43) Pub. Date: Sep. 4, 2025

(54) VAPOR DEPOSITION OF FILMS COMPRISING MOLYBDENUM

(71) Applicant: ASM IP Holding B.V., Almere (NL)

(72) Inventors: Bhushan Zope, Phoenix, AZ (US); Eric Christopher Stevens, Tempe, AZ (US); Shankar Swaminathan, Phoenix, AZ (US); Eric James Shero, Phoenix, AZ (US); Robert Brennan Milligan, Phoenix, AZ (US)

(21) Appl. No.: 19/209,969

(22) Filed: May 16, 2025

Related U.S. Application Data
(63) Continuation of application No. 17/353,262, filed on Jun. 21, 2021, now Pat. No. 12,354,877.
(60) Provisional application No. 63/043,271, filed on Jun. 24, 2020.

(51) Int. Cl. H01L 21/285; C23C 16/08; C23C 16/455; H01L 21/768

(52) U.S. Cl. CPC H01L 21/28568; C23C 16/08; C23C 16/45553; H01L 21/28556; H01L 21/76843

(57) ABSTRACT

Vapor deposition processes for forming thin films comprising molybdenum on a substrate are provide. In some embodiments the processes comprise a plurality of deposition cycles in which the substrate is separately contacted with a vapor phase molybdenum precursor comprising a molybdenum halide, a first reactant comprising CO, and a second reactant comprising H₂. In some embodiments the thin film comprises MoC, Mo₂C, or MoOC. In some embodiments the substrate is additionally contacted with a nitrogen reactant and a thin film comprising molybdenum, carbon and nitrogen is deposited, such as MoCN or MoOCN.

### REFERENCE TO RELATED APPLICATIONS

This application is a continuation of, and claims priority to, U.S. patent application Ser. No. 17/353,262 filed Jun. 21, 2021 titled VAPOR DEPOSITION OF FILMS COMPRISING MOLYBDENUM, which claims priority to U.S. Provisional Application No. 63/043,271, filed Jun. 24, 2020, the disclosures of which are incorporated herein by reference in their entirety.

### BACKGROUND OF THE INVENTION

### Field of the Invention

This application generally relates to vapor deposition processes for forming films comprising molybdenum. Thin films comprising molybdenum carbon can be deposited by cyclical vapor deposition processes, such as atomic layer deposition, for example using CO and H₂ as reducing agents.

### Description of the Related Art

Titanium nitride (TiN) is one of the most widely used materials in the semiconductor industry and as such is deposited for many purposes, e.g., liner, barrier/adhesion layers, etc. However, TiN films have relatively high resistivity and cannot be scaled to higher p-metal work function requirements for advanced IC nodes. Molybdenum carbide films can provide an alternative to TiN films. However, deposition processes for forming molybdenum films utilizing halide reactants have typically had the disadvantage of etching or contaminating other materials.

### SUMMARY

In one aspect, vapor deposition methods of depositing thin films comprising molybdenum are provided. In some embodiments, the thin films comprise molybdenum and carbon, such as molybdenum carbide (MoC, Mo₂C) thin films, molybdenum oxycarbide (MoOC) thin films, molybdenum oxycarbide nitride (MoOCN) thin films or molybdenum carbon nitride (MoCN) thin films by vapor deposition processes are provided. In some embodiments the deposition processes are atomic layer deposition (ALD) process.

In some embodiments a vapor deposition process for forming a thin film comprising molybdenum, such as a thin film comprising molybdenum and carbon, on a substrate in a reaction space comprises a plurality of deposition cycles comprising contacting the substrate with a first reactant comprising a vapor phase molybdenum precursor, such as a molybdenum halide, and subsequently contacting the substrate with a vapor phase second reactant for example comprising carbon and oxygen, such as CO, and a vapor phase third reactant comprising hydrogen, such as H₂. The deposition cycle may be repeated two or more times to form a thin film comprising molybdenum. In some embodiments the thin film comprises molybdenum and carbon. In some embodiments the substrate is alternately and sequentially contacted with the first reactant, the second reactant and the third reactant. In some embodiments the substrate is contacted with the first reactant and subsequently contacted simultaneously with the second and third reactants.

In some embodiments the thin film is a MoC, Mo₂C or MoOC thin film. In some embodiments the thin film is a MoOCN or MoCN thin film. In some embodiments the thin film is a molybdenum thin film.

In some embodiments the molybdenum precursor is a molybdenum halide, such as MoCl₅, MoBr₂ or MoI₃. In some embodiments the molybdenum precursor is a molybdenum oxyhalide, such as MoOCl₄ or MoO₂Cl₂.

In some embodiments the only reactants used in the deposition cycle are the molybdenum precursor, the second reactant and the third reactant. In some embodiments the only reactants used in the deposition cycle are the molybdenum precursor, CO and H₂.

In some embodiments the deposition process further comprises contacting the substrate with one or more additional reactants. In some embodiments a fourth reactant comprises nitrogen, for example a fourth reactant comprising NH₃. In some embodiments a fourth reactant comprises oxygen. In some embodiments the substrate is contacted with an oxygen reactant such as H₂O, O₃, H₂O₂, N₂O, NO₂ or NO. In some embodiments the substrate is contacted with a fourth reactant after contacting the substrate with the first reactant and prior to contacting the substrate with the second and the third reactants. In some embodiments the substrate is contacted with a fourth reactant after being contacted with the first, second and third reactants.

In some embodiments the deposition cycle comprises, in order, contacting the substrate with the first reactant comprising a molybdenum precursor, contacting the substrate with the second reactant such as CO and contacting the substrate with the third reactant such as H₂. In some embodiments the deposition cycle comprises, in order, contacting the substrate with the first precursor and subsequently simultaneously contacting the substrate with the second and third reactants. In some embodiment the third reactant further comprises NH₃. In some embodiments the substrate is separately contacted with a fourth reactant comprising NH₃.

In some embodiments a cobalt thin film is deposited over the molybdenum-containing thin film.

In some embodiments a deposition cycle for depositing molybdenum carbide or molybdenum oxycarbide comprises, in order, contacting a substrate with a first reactant comprising a molybdenum precursor, contacting the substrate with a second reactant comprising CO and contacting the substrate with a third reactant comprising H₂. In some embodiments the deposition cycle comprises, in order, contacting the substrate with the first precursor and subsequently simultaneously contacting the substrate with the second and third reactants.

In some embodiments a process for forming a thin film comprising molybdenum, carbon and nitrogen on a substrate in a reaction space comprises a deposition cycle comprising contacting the substrate with a first reactant comprising a molybdenum precursor, such as a molybdenum halide, and subsequently contacting the substrate with a second reactant comprising CO and a third reactant comprising NH₃.

The deposition cycle may be repeated two or more times to form a thin film of a desired thickness. In some embodiments excess reactant and reaction byproducts, if any, are removed from the reaction space after each contacting step, for example after contacting the substrate with the first reactant and prior to contacting the substrate with the second and/or third reactant.

In some embodiments the only reactants that are used in a deposition cycle are a molybdenum halide, CO and H₂. In some embodiments the only reactants that are used in a deposition cycle are a molybdenum halide, CO and NH₃. In some embodiments the third reactant comprises NH₃ and H₂. In some embodiments the only reactants that are used in a deposition cycle are a molybdenum halide, CO, H₂ and NH₃.

### BRIEF DESCRIPTION OF THE DRAWINGS

Embodiments described herein will be better understood from the Detailed Description and from the appended Drawings, which are meant to illustrate and not to limit the invention, and wherein:

FIG. 1A is a simplified cross section view of a semiconductor device structure according to certain embodiments.

FIG. 1B is a simplified cross section view of a gap-fill structure according to certain embodiments.

FIG. 2 is a flow chart illustrating processes for depositing metallic films comprising molybdenum and carbon by atomic layer deposition (ALD) deposition according to certain embodiments.

FIG. 3 is a flow chart illustrating processes for depositing metallic films comprising molybdenum and carbon by atomic layer deposition (ALD) deposition according to certain embodiments.

FIG. 4 is a flow chart illustrating processes for depositing metallic films comprising molybdenum and carbon by atomic layer deposition (ALD) deposition according to certain embodiments.

### DETAILED DESCRIPTION OF THE PREFERRED EMBODIMENT

Vapor deposition processes can be used to deposit material comprising molybdenum, such as thin films comprising molybdenum, thin films comprising molybdenum and carbon and thin films comprising molybdenum, carbon and nitrogen. In some embodiments the vapor deposition processes utilize a first reactant comprising a molybdenum precursor, such as a molybdenum halide, a second vapor phase reactant and a third vapor phase reactant. In some embodiments one or both of the second and third reactants can comprise a reducing agent. In some embodiments both the second and third reactants comprise a reducing agent. In some embodiments the second reactant comprises a carbon source, e.g., CO. In some embodiments the third reactant comprises H₂ and/or NH₃. In some embodiments, the third vapor phase reactant may comprise hydrazine. In some embodiments an additional reactant is utilized and may also comprise, for example, H₂ and/or NH₃. In some embodiments an additional reactant comprising oxygen may be utilized, for example as H₂O, O₃, H₂O₂, N₂O, NO₂ or NO. In some embodiments thin films comprising molybdenum, such as molybdenum films, thin films comprising molybdenum and carbon such as molybdenum carbide (e.g., MoC, Mo₂C) thin films, molybdenum oxycarbide (MoOC) thin films, or thin films comprising molybdenum, carbon and nitrogen, such as molybdenum oxycarbon nitride (MoOCN) thin films or molybdenum carbon nitride (MoCN) thin films are deposited by vapor deposition processes. In some embodiments the vapor deposition processes are atomic layer deposition (ALD) processes.

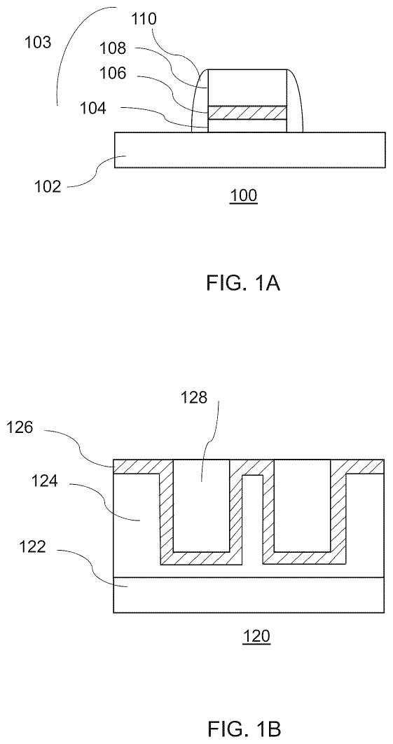

In some embodiments thin films comprising molybdenum or molybdenum and carbon, such as molybdenum carbide, molybdenum oxycarbide, molybdenum carbon nitride or molybdenum oxycarbon nitride, are deposited by the disclosed methods and can be used in any of a variety of contexts, for example, as a gate material in a CMOS structure or as a barrier/adhesion layer for a gap fill structure, for example as illustrated in FIGS. 1A and 1B. In some embodiments the thin films can be used as an adhesion layer in a cobalt gap-fill process. In some embodiments the thin films can be used as a low-resistivity P-metal for a metal gate. In some embodiments the thin films can be used as a low resistivity barrier or nucleation layer for metallization in logic or memory applications.

As non-limiting examples, FIG. 1A is a simplified cross-sectional view of a semiconductor device structure 100 according to certain embodiments, and FIG. 1B is a simplified cross-sectional view of a gap-fill structure 120 according to certain embodiments. Referring to FIG. 1A, the semiconductor device structure 100 comprises a substrate 102 and a gate structure 103 on the substrate 102. The gate structure 103 comprises a gate dielectric layer 104 on the substrate, a gate metal layer 106 comprising molybdenum and carbon, such as MoC, Mo₂C, MoOC, MoOCN or MoCN, on the gate dielectric layer 104, and a conductive layer 108 on the gate metal layer 106. A spacer 110 may be formed on sidewalls of the gate dielectric layer 104, the gate metal layer 106, and the conductive layer 108. In some embodiments, the gate metal layer 106 can comprise molybdenum and carbon and can be formed by a vapor deposition process as described herein, such as by an atomic layer deposition process. In some embodiments, the gate metal layer 106 can comprise molybdenum oxycarbide.

Referring to FIG. 1B, the gap-fill structure 120 comprises a substrate 122, a dielectric layer 124, a barrier/adhesion layer 126 comprising molybdenum and carbon, such as MOC, Mo₂C, MoOC, MoOCN, or MoCN, and a gap-fill layer 128. The dielectric layer 124 is patterned and the barrier/adhesion layer 126 is formed conformally on the patterned dielectric layer, e.g., on the bottom and side of a recess. The gap-fill layer 128 fills the recess. In some embodiments, the barrier/adhesion layer 126 can be formed by a vapor deposition process as described herein, such as by an atomic layer deposition process. In some embodiments the gap-fill layer 128 comprises cobalt. In some embodiments, the barrier/adhesion layer 126 can comprise molybdenum oxycarbide.

The gate metal layer 106 comprising molybdenum and carbon, such as MoC, Mo₂C, MoOC, MoOCN, or MoCN, and the barrier/adhesion layer 126 comprising molybdenum and carbon, such as MoC, Mo₂C, MoOC, MoOCN, or MoCN, can provide low resistivity as compared to TiN that is typically used in these contexts. Other contexts in which the disclosed molybdenum- and carbon-containing thin films may be utilized will be apparent to the skilled artisan.

### Atomic Layer Deposition (ALD)

As noted above, vapor deposition processes are provided for depositing material comprising molybdenum, or molybdenum and carbon, such as Mo, MoC, Mo₂C, MoOC, MoOCN, or MoCN thin films. In some embodiments the vapor deposition processes are atomic layer deposition processes in which a substrate surface is alternately and sequentially contacted with two or more reactants.

In some embodiments a material comprising molybdenum is deposited on a substrate in a reaction space by contacting the substrate surface with three reactants: a first reactant comprising a molybdenum precursor, a second reactant and a third reactant. In some embodiments the second reactant comprises carbon, such as CO. In some embodiments the third reactant comprises H₂ and/or NH₃. In some embodiments the second reactant comprises a first reducing agent and the third reactant comprises a second reducing agent. In some embodiments the first reducing agent is different from the second reducing agent. In some embodiments the first reducing agent and the second reducing agent are the same. In some embodiments the first reducing agent may comprise carbon. In some embodiments the second reducing agent comprises hydrogen. In some embodiments a first reactant comprises a molybdenum precursor, a second reactant comprises CO and a third reactant comprises H₂. In some embodiments a deposition process comprises a deposition cycle in which a substrate in a reaction chamber is alternately and sequentially contacted with a first reactant comprising a vapor phase molybdenum precursor, a second reactant comprising a first reducing agent and a third reactant comprising a second reducing agent. In some embodiments a substrate in a reaction chamber is alternately and sequentially contacted with a first reactant comprising a vapor phase molybdenum precursor, a second reactant comprising CO and a third reactant comprising H₂. In some embodiments the substrate is contacted simultaneously with the second and third reactants. The deposition cycle may be repeated two or more times to deposit a thin film of a desired thickness.

Although called the first reactant, second reactant and third reactant they are not necessarily contacted with the substrate in that order in the deposition cycle. In some embodiments the reactants are contacted with the substrate in the order of the first reactant, second reactant and third reactant. In some embodiments the substrate is contacted with one or both of the second or third reactants before the first reactant. In some embodiments the substrate is contacted sequentially with the first reactant comprising the molybdenum precursor and then with the second and third reactants.

In some embodiments the substrate is contacted first with the first reactant comprising the molybdenum precursor and then subsequently contacted simultaneously with the second and third reactants, for example with CO and H₂. In some embodiments the first reactant comprising the molybdenum precursor, the second reactant and the third reactant are the only reactants utilized in a deposition cycle. In some embodiments the molybdenum precursor, CO and H₂ are the only reactants utilized in a deposition cycle. In some embodiments the thin film deposited using the molybdenum precursor, CO and H₂ comprises Mo, MoC, Mo₂C, or MoOC. In some embodiments the ratio of CO and H₂ can be tuned to deposit MoOC. Tuning may be accomplished, for example, by adjusting the exposure time of the substrate to each of the reactants or by adjusting the ratio of the reactants that are provided in the entire deposition process.

In some embodiments a material comprising molybdenum, carbon and nitrogen is deposited on a substrate in a reaction space by contacting the substrate surface with a first reactant comprising a molybdenum precursor, a second reactant comprising a first reducing agent and a third reactant comprising a nitrogen reactant, such as NH₃. In some embodiments a deposition process comprises a deposition cycle in which a substrate is alternately and sequentially contacted with a first reactant comprising a vapor phase molybdenum precursor, a second reactant comprising carbon, such as CO and a third reactant comprising nitrogen, such as NH₃. In some embodiments the substrate may be contacted simultaneously with the second and third reactants. The deposition cycle may be repeated two or more times to deposit a thin film of a desired thickness.

Although called the first reactant, second reactant and third reactant they are not necessarily contacted with the substrate in that order in the deposition cycle. In some embodiments the reactants are contacted with the substrate in the order of the first reactant, second reactant and third reactant. In some embodiments the substrate is contacted with one or both of the second or third reactants before the first reactant. In some embodiments the substrate is contacted sequentially with the first reactant comprising the molybdenum precursor and then with the second and third reactants.

In some embodiments a deposition process comprises a deposition cycle in which a substrate is alternately and sequentially contacted with a first reactant comprising a vapor phase molybdenum precursor, CO and NH₃. In some embodiments the substrate is contacted simultaneously with the CO and NH₃. In some embodiments the substrate is contacted sequentially with the first reactant comprising the molybdenum precursor and then with the second and third reactants. In some embodiments the substrate is contacted first with the first reactant comprising the molybdenum precursor and then subsequently contacted simultaneously with the second and third reactant, for example with CO and NH₃. In some embodiments the molybdenum precursor, CO and NH₃ are the only reactants utilized in a deposition cycle. In some embodiments the thin film comprises MoCN or MoOCN. In some embodiments the ratio of CO to NH₃ can be tuned to deposit MoOCN.

In some embodiments a material comprising molybdenum, carbon and nitrogen is deposited on a substrate in a reaction space by contacting the substrate surface with a first reactant comprising a molybdenum precursor, a second reactant comprising a first reducing agent, a third reactant comprising a second reducing agent, such as H₂ and a fourth reactant comprising a nitrogen reactant, such as NH₃. In some embodiments a deposition process comprises a deposition cycle in which a substrate is alternately and sequentially contacted with a first reactant comprising a vapor phase molybdenum precursor, a second reactant comprising carbon, such as CO, a third reactant comprising H₂ and a fourth reactant comprising nitrogen, such as NH₃. In some embodiments the substrate is contacted simultaneously with at least two of the second, third and fourth reactants. In some embodiments the substrate is contacted simultaneously with the second and third reactants. In some embodiments the substrate is contacted simultaneously with the third and fourth reactants. In some embodiments the substrate is contacted simultaneously with the second and fourth reactants. In some embodiments the substrate is contacted simultaneously with the second, third and fourth reactants. The deposition cycle may be repeated two or more times to deposit a thin film of a desired thickness.

Although called the first reactant, second reactant, third reactant and fourth reactant they are not necessarily contacted with the substrate in that order in the deposition cycle. In some embodiments the reactants are contacted with the substrate in the order of the first reactant, second reactant, third reactant and fourth reactant. In some embodiments the substrate is contacted with one or more of the second, third and/or fourth reactants before the first reactant. In some embodiments the substrate is contacted sequentially with the first reactant comprising the molybdenum precursor and then with the first, second and third reactants.

In some embodiments the substrate is alternately and sequentially contacted with a first reactant comprising a vapor phase molybdenum precursor, CO, H₂ and NH₃. In some embodiments the substrate is contacted simultaneously with the CO, H₂ and/or NH₃. In some embodiments a substrate is alternately and sequentially contacted with a first reactant comprising a vapor phase molybdenum precursor, CO, H₂ and NH₃. In some embodiments the substrate is contacted with the first reactant comprising the molybdenum precursor and then separately contacted with one of CO, H₂ and NH₃ and then simultaneously contacted with two or more of the others of the CO, H₂ and NH₃.

In some embodiments the substrate is contacted sequentially with first reactant comprising the molybdenum precursor, the second reactant and then contacted simultaneously with the third and fourth reactants. For example, the substrate may be contacted sequentially with the first reactant comprising the molybdenum precursor and CO and then contacted simultaneously with H₂ and NH₃. In some embodiments the substrate is contacted first with the first reactant comprising the molybdenum precursor and then subsequently contacted simultaneously with the second, third and fourth reactants, for example with CO, H₂ and NH₃. In some embodiments the first reactant comprising a molybdenum precursor, the second reactant comprising carbon, such as CO, the third reactant comprising a reducing agent such as H₂ and the fourth reactant comprising a nitrogen reactant, such as NH₃, are the only reactants used in a deposition cycle. In some embodiments the molybdenum precursor, CO, H₂ and NH₃ are the only reactants utilized in the deposition cycle. In some embodiments the thin film comprises MoOCN, or MoCN. In some embodiments the ratio of the second reactant to the third reactant and fourth reactant is tuned to preferentially deposit MoCN or MoOCN.

In some embodiments the molybdenum precursor comprises a molybdenum halide. In some embodiments the molybdenum precursor comprises a molybdenum oxyhalide. For example, in some embodiments the molybdenum precursor may comprise at least one of MoO₂Cl₂, MoCl₅, MoOCl₄, MoBr₂, or MoI₃. In some embodiments, the molybdenum precursors may consist of at least one of MoO₂Cl₂, MoCl₅, MoOCl₄, MoBr₂, or MoI₃.

In some embodiments a molybdenum oxyhalide is used in a deposition process to deposit Mo, MoOC or MoOCN. For example, in some embodiments Mo films are deposited by a deposition cycle in which the substrate is contacted with a first reactant comprising a molybdenum precursor comprising MoO₂Cl₂ or MoOCl₄, a second reactant comprising carbon, such as CO and a third reactant comprising a reducing agent, such as H₂. In some embodiments the second reactant comprises a reducing agent and the reducing agents in the first and second reactants are different. In some embodiments the reducing agents may be the same.

In some embodiments, the deposition process is an atomic layer deposition (ALD) process. In some embodiments conformal thin films comprising molybdenum and carbon are deposited, for example on a three-dimensional structure on a substrate. Among vapor deposition techniques, ALD has the advantage of typically providing high conformality at low temperatures.

ALD type processes are based on controlled, surface reactions of precursor chemicals. In some embodiments the surface reactions are generally self-limiting. Gas phase reactions are typically avoided by feeding the precursors alternately and sequentially into the reaction chamber. Vapor phase reactants are separated from each other in the reaction chamber, for example, by removing excess reactants and/or reactant by-products from the reaction chamber between reactant pulses.

Before starting the deposition of the film, the substrate is typically heated to a suitable growth temperature, as discussed above. Briefly, a substrate is heated to a suitable deposition temperature, generally at lowered pressure. The preferred deposition temperature may vary depending on a number of factors such as, and without limitation, the reactant precursors, the pressure, flow rate, the arrangement of the reactor, and the composition of the substrate including the nature of the material to be deposited on. Deposition temperatures are generally maintained below the thermal decomposition temperature of the reactants but at a high enough level to avoid condensation of reactants and to provide the activation energy for the desired surface reactions. Of course, the appropriate temperature window for any given ALD reaction will depend upon the surface termination and reactant species involved. Here, the temperature varies depending on the precursors being used and is generally at or below about 700° C. In some embodiments the deposition temperature is generally at or above about 100° C. and at or below about 700° C. In some embodiments the deposition temperature is between about 200° C. and about 700° C., and in some embodiments the deposition temperature is between about 300° C. and about 500° C. In some embodiments, the deposition temperature is below about 500° C., below about 400° C. or below about 300° C. In some instances the deposition temperature can be above about 200° C., above about 150° C. or above about 100° C. In some embodiments lower deposition temperatures can be achieved, for example, if additional reactants or reducing agents, such as reactants or reducing agents comprising hydrogen, are used in the process.

In a deposition cycle, the surface of the substrate is contacted with a first reactant comprising a vapor phase molybdenum precursor, also referred to as a molybdenum precursor. In some embodiments a pulse of vapor phase molybdenum precursor is provided to a reaction space containing the substrate (for example, in time divided ALD). In some embodiments the substrate is moved to a reaction space containing vapor phase molybdenum precursor (for example, in space divided ALD, also known as spatial ALD). Conditions can be selected such that no more than about one monolayer of the molybdenum precursor or a species thereof is adsorbed on the first surface of the substrate. Conditions may be selected such that the precursor adsorbs in a self-limiting manner. The appropriate contacting times can be readily determined by the skilled artisan based on the particular circumstances. Excess first reactant and reaction byproducts, if any, are removed from the substrate surface, such as by purging with an inert gas or by removing the substrate from the presence of the first reactant.

The molybdenum precursor and additional reactants are typically kept separated and contact the substrate separately. In particular, the molybdenum precursor is typically provided separately from the other reactants. However, as discussed herein, in some embodiments two or more of the additional reactants can be provided together. Moreover, in some arrangements, such as hybrid CVD/ALD, or cyclical CVD, processes can allow overlap of the different mutually reactive reactants over the substrate and thus can produce more than a monolayer per cycle. Vapor phase precursors and/or vapor phase byproducts are removed from the substrate surface, such as by evacuating a chamber with a vacuum pump and/or by purging (for example, replacing the gas inside a reactor with an inert gas such as argon or nitrogen). Supply of the precursor or reactant to the substrate surface is typically stopped during the removal periods, and may be shunted to a different chamber or to a vacuum pump during the removal periods. Typical removal times are from about 0.05 to 20 seconds, from about 1 to 10 seconds, or from about 1 to 2 seconds. However, other removal times can be utilized if necessary, such as where highly conformal step coverage over extremely high aspect ratio structures or other structures with complex surface morphology is needed.

The surface of the substrate is contacted with a vapor phase second reactant. In some embodiments the second reactant comprises a first reducing agent In some embodiments the second reactant comprises carbon. In some embodiments the second reactant comprises CO. In some embodiments the second reactant comprises CO and H₂. In some embodiments the second reactant comprises CO, H₂ and NH₃. In some embodiments, a pulse of a second reactant is provided to a reaction space containing the substrate. In some embodiments, the substrate is moved to a reaction space containing the vapor phase second reactant. Excess second reactant and gaseous byproducts of the surface reaction, if any, are removed from the substrate surface. In some embodiments a deposition cycle comprises alternately and sequentially contacting the substrate with the molybdenum precursor and the second reactant. In some embodiments one or more additional reactants are utilized.

In some embodiments, following removal of the second reactant and gaseous byproducts, in some embodiments the surface of the substrate is contacted with a third vapor phase reactant or precursor. In some embodiments the third vapor phase reactant comprises a second reducing agent. In some embodiments the second reducing agent is different from the first reducing agent. In some embodiments the second reducing agent is the same as the first reducing agent. In some embodiments the third vapor phase reactant comprises hydrogen. In some embodiments the third vapor phase reactant comprises H₂. In some embodiments the third vapor phase reactant comprises NH₃. In some embodiments the third vapor phase reactant comprises both NH₃ and H₂. In some embodiments, a pulse of a third reactant is provided to a reaction space containing the substrate. In some embodiments, the substrate is moved to a reaction space containing the vapor phase third reactant. Excess third reactant and gaseous byproducts of the surface reaction, if any, are removed from the substrate surface.

In some embodiments the second and third reactants may be provided simultaneously or in overlapping pulses. For example, in some embodiments a second reactant comprising CO and a third reactant comprising H₂ are provided simultaneously or in overlapping pulses.

In some embodiments the substrate may be contacted with a fourth vapor-phase reactant. In some embodiments the fourth vapor-phase reactant comprises a third reducing agent. In some embodiments the fourth vapor-phase reactant comprises one or both of H₂ and/or NH₃. In some embodiments the third vapor phase reactant is one of H₂ or NH₃ and the fourth vapor phase reactant is the other of H₂ and NH₃. For example, in some embodiments the third vapor phase reactant comprises H₂ and the fourth vapor phase reactant comprises NH₃. In some embodiments, a pulse of a fourth reactant is provided to a reaction space containing the substrate. In some embodiments, the substrate is moved to a reaction space containing the vapor phase fourth reactant. Excess fourth reactant and gaseous byproducts of the surface reaction, if any, are removed from the substrate surface.

In some embodiments two or more of the second, third and fourth reactants may be provided simultaneously or in overlapping pulses. For example, in some embodiments a third reactant comprising H₂ and a fourth reactant comprising NH₃ are provided simultaneously or in overlapping pulses. In some embodiments the substrate is separately contacted with the first reactant comprising the molybdenum precursor, even if it is contacted simultaneously with two or more of the additional reactants.

Although referred to as first, second, third and fourth reactants, the reactants may be provided in different orders. In some embodiments the molybdenum precursor is provided before any of the other reactants. In some embodiments the molybdenum precursor is provided after one or more of the additional reactants. In some embodiments the reactants are provided in the same order in each deposition cycle. In some embodiments the reactants are provided in different orders in different deposition cycles.

Contacting and removing are repeated until a thin film of the desired thickness has been formed on the substrate, with each cycle leaving no more than about a molecular monolayer in an ALD or ALD type process, or one or more molecular monolayers in a hybrid CVD/ALD, or cyclical CVD process.

Each reactant is conducted or pulsed into the chamber in the form of vapor phase pulse and contacted with the surface of a substrate. In some embodiments the substrate surface comprises a three-dimensional structure. In some embodiments conditions are selected such that no more than about one monolayer of each precursor is adsorbed on the substrate surface in a self-limiting manner.

Excess precursor or reactant and reaction byproducts, if any, may be removed from the substrate and substrate surface and/or from the proximity to the substrate and substrate surface between pulses of each precursor or reactant. In some embodiments reactant and reaction byproducts, if any, may be removed by purging. Purging may be accomplished for example, with a pulse of inert gas such as nitrogen or argon.

In some embodiments excess precursors (or reactants and/or reaction byproducts, etc.) are removed from the substrate surface or from the area of the substrate by physically moving the substrate from a location containing the precursor, reactant and/or reaction byproducts.

The precursors and reactants employed in the processes may be solid, liquid, or gaseous material under standard conditions (room temperature and atmospheric pressure), provided that they are in vapor phase before they are conducted into the reaction chamber and contacted with the substrate surface.

The steps of contacting the substrate with each precursor and reactant, such as by pulsing, and removing excess precursor or reactant and reaction byproducts are repeated until a thin film of the desired thickness has been formed on the substrate, with each complete cycle typically leaving no more than about a molecular monolayer.

“Pulsing” a vaporized reactant onto the substrate means that the vapor is conducted into the chamber for a limited period of time such that the substrate is exposed to the reactant. Typically, the pulsing time is from about 0.05 seconds to about 60 seconds or even longer. In some embodiments the first reactant comprising a molybdenum precursor is pulsed for about 0.05 to about 10 seconds. In some embodiments other reactants, such as reactants comprising a reducing agent, carbon, nitrogen or hydrogen may be pulsed for about 0.05 to about 60 seconds or longer. However, actual pulsing times can be determined depending on the particular reaction conditions, including substrate type and its surface area.

As an example, for a 300 mm wafer in a single wafer ALD reactor, the molybdenum precursors are typically pulsed for from about 0.05 seconds to about 10 seconds while reducing agents may be pulsed for about 0.05 to about 60 seconds. However, pulsing times can be on the order of minutes in some cases. Again, the optimum pulsing time can be readily determined by the skilled artisan based on the particular circumstances.

The mass flow rate of the reactants can be determined by the skilled artisan. In some embodiments, for example for deposition on 300 mm wafers, the flow rate of the reactants is preferably between about 5 sccm and about 1000 sccm, about 10 sccm to about 800 sccm, or about 50 sccm to about 500 sccm.

The pressure in the reaction chamber is typically from about 1 to 70 Torr, or from about 2 to 40 Torr. However, in some cases the pressure will be higher or lower than this range, as can be readily determined by the skilled artisan depending on multiple parameters, such as the particular reactor being used, the process and the precursors.

As mentioned above, each pulse or phase of each cycle is preferably self-limiting. An excess of reactant is supplied in each phase to saturate the susceptible structure surfaces. Surface saturation ensures reactant occupation of all available reactive sites (subject, for example, to physical size or “steric hindrance” restraints) and thus ensures excellent step coverage. In some arrangements, the degree of self-limiting behavior can be adjusted by, e.g., allowing some overlap of reactant pulses to trade off deposition speed (by allowing some CVD-type reactions) against conformality. Ideal ALD conditions with reactants well separated in time and space provide near perfect self-limiting behavior and thus maximum conformality, but steric hindrance results in less than one molecular layer per cycle. Limited CVD reactions mixed with the self-limiting ALD reactions can raise the deposition speed.

In some embodiments, a reaction space can be in a single-wafer ALD reactor or a batch ALD reactor where deposition on multiple substrates takes place at the same time. In some embodiments the substrate on which deposition is desired, such as a semiconductor workpiece, is loaded into a reactor. The reactor may be part of a cluster tool in which a variety of different processes in the formation of an integrated circuit are carried out. In some embodiments a flow-type reactor is utilized. In some embodiments a high-volume manufacturing-capable single wafer ALD reactor is used. In other embodiments a batch reactor comprising multiple substrates is used.

Examples of suitable reactors that may be used include commercially available ALD equipment. In addition to ALD reactors, many other kinds of reactors capable of ALD growth of thin films, including CVD reactors equipped with appropriate equipment and means for pulsing the precursors can be employed. In some embodiments a flow type ALD reactor is used. Preferably, reactants are kept separate until reaching the reaction chamber, such that shared lines for the precursors are minimized. However, other arrangements are possible.

In some embodiments batch reactors are utilized. In some embodiments in which a batch reactor is used, wafer-to-wafer uniformity is less than 3% (1sigma), less than 2%, less than 1% or even less than 0.5%.

The deposition processes described herein can optionally be carried out in a reactor or reaction space connected to a cluster tool. In a cluster tool, because each reaction space is dedicated to one type of process, the temperature of the reaction space in each module can be kept constant, which can improve the throughput compared to a reactor in which the substrate is heated up to the process temperature before each run.

In some embodiments, Mo, MOC, Mo₂C, MoOC, MoOCN, or MoCN thin films are deposited by a deposition cycle comprising alternately and sequentially contacting a substrate with a first reactant comprising a molybdenum precursor, a second reactant comprising carbon and oxygen, such as a second reactant comprising carbon monoxide (CO), and at least one third reactant comprising hydrogen, such as H₂, or ammonia (NH₃). In some embodiments the first reactant can be a molybdenum halide. In some embodiments, the first reactant can be a molybdenum oxyhalide. For example, in some embodiments the first reactant may comprise at least one of MoO₂Cl₂, MoCl₅, MoOCl₄, MoBr₂, or MoI₃. In some embodiments, the first reactant may consist of at least one of MoO₂Cl₂, MoCl₅, MoOCl₄, MoBr₂, or MoI₃. In some embodiments where Mo is being deposited, the first reactant may be a molybdenum oxyhalide, for example a molybdenum oxychloride such as MoO₂Cl₂ or MoOCl₄.

In some embodiments where Mo, MoC, MoOC or Mo₂C is being deposited, hydrogen may be used as the reactant comprising hydrogen. In some embodiments where incorporating nitrogen in the deposited material is desired, such as MoOCN, MoCN, a reactant comprising ammonia may be used as the reactant comprising hydrogen.

In some embodiments, a molybdenum precursor comprising oxygen is used and the reactant comprising carbon and oxide can remove oxygen from the molybdenum precursor and contribute carbon to the growing MoC, MoOC, Mo₂C or MoCN thin film. The hydrogen reactant can remove halide ligands, and, in the case of ammonia can both remove halide and contribute nitrogen to the growing MoCN thin films. The deposition cycle is repeated to deposit a film of the desired thickness.

In some embodiments one or more of the reactants (CO, H₂ and NH₃) may be provided after the molybdenum precursor. In some embodiments, the molybdenum precursor is contacted with the substrate first, followed by the reactant comprising carbon and oxide, and the at least one reactant such as hydrogen or ammonia sequentially. In some embodiments, the molybdenum precursor is contacted with the substrate first, followed by the at least one reactant such as hydrogen or ammonia, and the reactant comprising carbon and oxide sequentially.

For example, in some embodiments, the film deposition cycle (comprises three phases. In a first phase the substrate is contacted with only the first reactant comprising a molybdenum precursor. In a second phase the substrate comprising species of the molybdenum precursor is contacted with a second reactant comprising CO. In a third phase the substrate is contacted with a third reactant comprising hydrogen, such as at least one of an ammonia reactant and a hydrogen reactant. In some embodiments the second and third phases are combined, such that in a first phase the substrate is only contacted with a molybdenum precursor while in a second phase the substrate is contacted with CO, H₂ and/or NH₃.

In some embodiments the first reactant is provided after at least one of the other reactants. In some embodiments, the substrate is contacted with at least one of the carbon monoxide reactant, the hydrogen reactant, or the ammonia reactant after the first reactant. For example, in some embodiments the carbon monoxide reactant is contacted with the substrate, then the first reactant is contacted with the substrate, and at least one of the hydrogen reactant, or the ammonia reactant can contacted with the substrate. In some embodiments, the at least one of the hydrogen reactant, or the ammonia reactant can contacted with the substrate, then the first reactant is contacted with the substrate, and the carbon monoxide reactant is contacted with the substrate.

The deposition cycle is repeated to deposit a thin film comprising molybdenum and carbon, such an MoC, MoOC, Mo₂C, MoOCN or MoCN film of the desired thickness.

In some embodiments, MoC, MoOC, or Mo₂C are deposited by a deposition cycle comprising alternately and sequentially contacting a substrate with a first reactant comprising a molybdenum precursor, a second reactant comprising carbon monoxide, and a third reactant comprising H₂. In some embodiments the second reactant comprising carbon monoxide and the third reactant comprising H₂ are provided together. That is, in some embodiments the substrate may be separately contacted with the first reactant comprising the molybdenum precursor and simultaneously contacted with the second reactant comprising carbon monoxide and the third reactant comprising H₂.

In some embodiments MoOCN, or MoCN thin films are deposited by a deposition cycle comprising alternately and sequentially contacting a substrate with a first reactant comprising molybdenum precursor, a second reactant comprising carbon monoxide, and a third reactant comprising ammonia. In some embodiments the second reactant comprising carbon monoxide and the third reactant comprising ammonia are provided together. That is, in some embodiments the substrate may be separately contacted with the first reactant comprising the molybdenum precursor and simultaneously contacted with the second reactant comprising carbon monoxide and the third reactant comprising ammonia. In some embodiments an additional reactant comprising H₂ is included in one or more deposition cycles. Thus, in some embodiments MoOCN or MoCN thin films are deposited using at least one deposition cycle comprising alternately and sequentially contacting a substrate with the first reactant comprising the molybdenum precursor, the second reactant comprising carbon monoxide, the third reactant comprising ammonia and the reactant fourth comprising H₂. In some embodiments two or more of the reactants comprising carbon monoxide, ammonia and H₂ may be provided together. For example, the substrate may be alternately and sequentially contacted with the first reactant comprising the molybdenum precursor, the second reactant comprising CO and a reactant comprising both H₂ and NH₃. The deposition cycle is repeated to deposit a film of the desired thickness. In some embodiments for depositing MoOC or MoOCN, the molybdenum precursor is a molybdenum oxyhalide and the ratio of the additional reactants is tuned to deposit the desired material.

In some embodiments the order of provision of the reactant may be varied. For example, in some embodiments in a deposition cycle each of the reactants (CO, H₂ and/or NH₃) may be provided after the first reactant comprising the molybdenum precursor. For example, one of the carbon monoxide reactant, the hydrogen reactant and/or the ammonia reactant contacts the substrate after the molybdenum precursor and reacts with adsorbed species of the molybdenum precursor. In some embodiments one or more of the reactants may be provided before the molybdenum precursor in the deposition cycle. In that case, the reactant or reactants provided before the molybdenum precursor will react with adsorbed molybdenum species in the subsequent deposition cycle. In some embodiments, the order of the additional reactants does not matter. In some embodiments, the carbon monoxide reactant is provided before an H₂ or NH₃ reactant. In other embodiments an H₂ or NH₃ reactant is provided prior to the carbon monoxide reactant.

In some embodiments, at least one deposition cycle may comprise another treatment phase in which the substrate is separately contacted with a vapor phase reactant comprising oxygen, such as H₂O, O₃, H₂O₂, N₂O, NO₂ or NO. This may be called an oxidation phase. In some embodiment, the oxidation phase may be performed after contacting the substrate with the first reactant comprising the molybdenum precursor. In some embodiments, the oxidation phase may be conducted last in the deposition cycle. For example, a deposition cycle may comprise contacting the substrate with a first reactant comprising a molybdenum precursor, contacting the substrate with a second reactant comprising CO, contacting the substrate with a third reactant comprising H₂ and/or NH₃, and contacting the substrate with a reactant comprising oxygen. In some embodiments an oxidation phase is included in one deposition cycle. In some embodiments an oxidation phase is included in multiple deposition cycles, or in each deposition cycle. In some embodiments an oxidation phase is included at intervals in the deposition process.

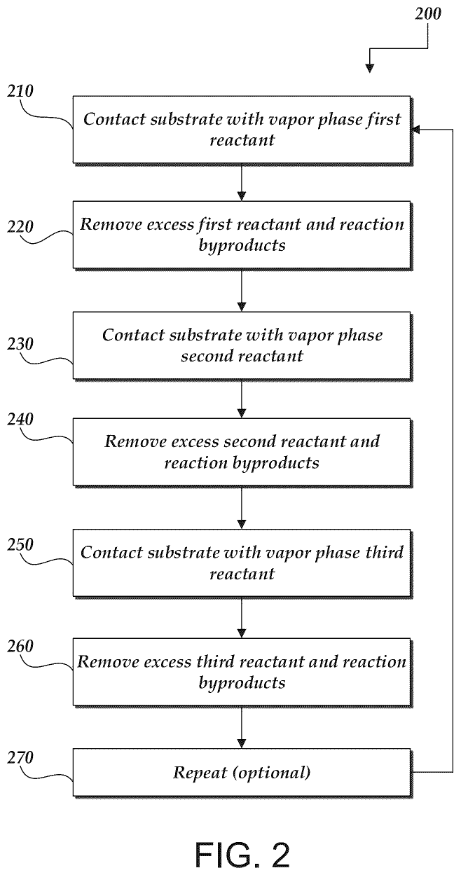

FIG. 2 is a flow-chart illustrating a deposition process 200 for depositing a thin film comprising molybdenum according to some embodiments. Referring to FIG. 2, the thin film comprising molybdenum is deposited on a substrate in a reaction space by the deposition process 200. The deposition process 200 comprises at least one deposition cycle comprising contacting the surface of the substrate with a first reactant comprising a vapor phase molybdenum precursor at block 210, removing excess molybdenum precursor and reaction byproducts, if any, from the surface at block 220, contacting the surface of the substrate with a vapor phase second reactant at block 230, removing any excess second reactant and reaction byproducts, if any, from the surface of the substrate at block 240, contacting the surface of the substrate with a vapor phase third reactant at block 250, and removing any excess third reactant and reaction byproducts, if any, from the surface of the substrate at block 260. The contacting and removing steps 210-260 can optionally be repeated at block 270 form the thin film comprising molybdenum of a desired thickness. For example, Mo, MoC, Mo₂C, MoOC, MoOCN, or MoCN thin films can be deposited.

In some embodiments, the molybdenum precursor may comprise a molybdenum halide, as discussed above. In some embodiments the molybdenum precursor may comprise a molybdenum oxyhalide. For example, the molybdenum precursor may comprise at least one of MoO₂Cl₂, MoCl₅, MoOCl₄, MoBr₂, or MoI₃. In some embodiments, the precursors may consist of at least one of MoO₂Cl₂, MoCl₅, MoOCl₄, MoBr₂, or MoI₃.

In some embodiments, the second reactant may comprise a first reducing agent. In some embodiments the second reactant comprises carbon and oxygen, such as carbon monoxide (CO). In some embodiments, the second reactant may consist of carbon monoxide (CO).

In some embodiments, the third reactant may comprise a nitrogen reactant, such as ammonia (NH₃). In some embodiments, the third reactant may consist of ammonia (NH₃).

In some embodiments, the third reactant may comprise a second reducing agent. In some embodiments the third reactant may comprise hydrogen, such as H₂. In some embodiments, the third reactant may consist of hydrogen, such as H₂.

In some embodiments, a Mo, MoC, MoOC or Mo₂C film may be deposited by the process illustrated in FIG. 2. In some embodiment, the molybdenum precursor comprises a molybdenum halide, such as MoOCl₄ or MoO₂Cl₂, the second reactant comprises CO, and the third reactant comprises H₂. In some embodiment, the second reactant comprises H₂, and the third reactant comprises CO. The deposition of MoC, MoOC or Mo₂C may be controlled, for example by tuning a ratio of the second reactant and the third reactant in the overall deposition process. That is, in some deposition cycles the second or third reactant may be omitted to adjust the ratio of times the substrate is contacted with the second and third reactants in the total deposition process.

In some embodiments the only reactants used in the deposition cycle are the molybdenum precursor, CO and H₂.

In some embodiments, a MoCN thin film may be deposited. In some embodiment, the molybdenum precursor comprises a molybdenum halide, such as MoOCl₄ or MoO₂Cl₂, the second reactant comprises CO, and the third reactant comprises NH₃. In some embodiments the second reactant comprises NH₃, and the third reactant comprises CO.

In some embodiments the only reactants used in the deposition cycle are the molybdenum precursor, CO and NH₃.

In some embodiments the above described cyclical deposition process 200 may be an ALD type process. In some embodiments the cyclical deposition process 200 may be an ALD process. In some embodiments the above-described cyclical process 200 may be a hybrid ALD/CVD or cyclical CVD process.

Although the illustrated deposition cycle begins with contacting the surface of the substrate with the first reactant comprising vapor phase molybdenum precursor 210, in other embodiments the deposition cycle may begin with contacting the surface of the substrate with the second reactant 230 or the third reactant 250.

In some embodiments removing the precursors or reactant and any excess reaction byproducts at blocks 220, 240, 260 may comprise purging the reaction space or reaction chamber. Purging the reaction chamber may comprise the use of a purge gas and/or the application of a vacuum to the reaction space. Where a purge gas is used, the purge gas may flow continuously or may be flowed through the reaction space only after the flow of a reactant gas has been stopped and before the next reactant gas begins flowing through the reaction space. It is also possible to continuously flow a purge or non-reactive gas through the reaction chamber so as to utilize the non-reactive gas as a carrier gas for the various reactive species. Thus, in some embodiments, a gas, such as nitrogen, continuously flows through the reaction space while the molybdenum precursor and reactant are pulsed as necessary into the reaction chamber. Because the carrier gas is continuously flowing, removing excess reactant or reaction by-products is achieved by merely stopping the flow of reactant gas into the reaction space.

In some embodiments removing the precursors or reactant and any excess reaction byproducts at blocks 220, 240, 260 may comprise moving the substrate from a first reaction chamber to a second, different reaction chamber. In some embodiments removing the precursors or reactant and any excess reaction byproducts at blocks 220, 240, 260 may comprise moving the substrate from a first reaction chamber to a second, different reaction chamber under a vacuum.

In some embodiments the deposited thin film comprising molybdenum may be subjected to a treatment process after deposition. In some embodiments this treatment process may, for example, enhance the conductivity or continuity of the deposited thin film comprising molybdenum. In some embodiments a treatment process may comprise, for example an anneal process.

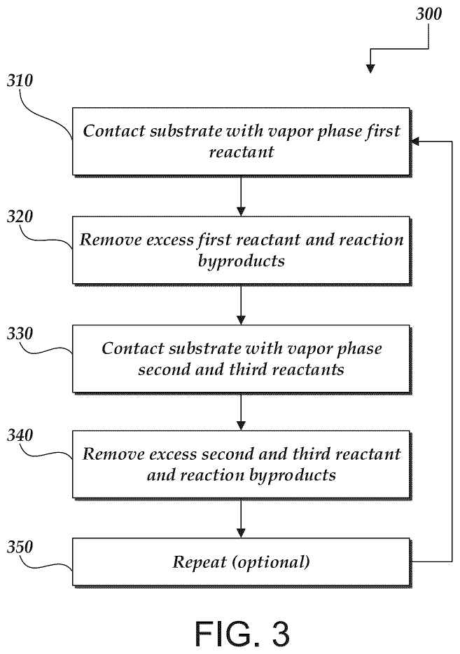

FIG. 3 is a flow-chart illustrating a deposition process 300 for depositing a thin film comprising molybdenum according to some embodiments. The deposition process 300 is similar to the deposition process 200 except that the second reactant and the third reactant are contacted with the substrate at the same time, such as by being co-flowed into the reaction space together. The deposition process 300 comprises at least one deposition cycle comprising contacting the surface of the substrate with a first reactant comprising a vapor phase molybdenum precursor at block 310, removing any excess molybdenum precursor and reaction byproducts, if any, from the surface at block 320, simultaneously contacting the surface of the substrate with a vapor phase second reactant and a vapor phase third reactant at block 330, and removing excess second and third reactants and reaction byproducts, if any, from the surface of the substrate at block 340. The deposition cycle comprising the contacting and removing steps 310-340 can be repeated at block 350 to form the thin film comprising molybdenum of a desired thickness. For example, Mo, MOC, Mo₂C, MoOC, MoOCN, or MoCN thin films can be deposited.

As indicated in FIG. 3, in some embodiments the molybdenum precursor comprises a molybdenum oxychloride. However, other molybdenum precursors may be used. In some embodiments the molybdenum precursor may comprise a molybdenum halide, such as a molybdenum oxyhalide. For example, the molybdenum precursor may comprise at least one of MoO₂Cl₂, MoCl₅, MoOCl₄, MoBr₂, or MoI₃. For example, the precursors may consist of at least one of MoO₂Cl₂, MoCl₅, MoOCl₄, MoBr₂, or MoI₃.

In some embodiments, the second reactant may comprise a first reducing agent. In some embodiments the second reactant comprises carbon. In some embodiments the second reactant comprises carbon and oxygen, such as carbon monoxide (CO). In some embodiments, the third reactant may comprise nitrogen, such as ammonia (NH₃). In some embodiments, the third reactant may comprise a second reducing agent. In some embodiments the third reactant may comprise hydrogen, such as H₂. In some embodiments the second reactant may comprise CO and the third reactant may comprise NH₃. In some embodiments the second reactant may comprise CO and the third reactant may comprise H₂. In some embodiments the second reactant may comprise CO and the third reactant may comprise both NH₃ and H₂.

Accordingly, in some embodiments, the second reactant and the third reactant may comprise CO, and H₂ and they may be flowed into the reaction space together. In some embodiments, the second reactant and the third reactant may comprise CO, and NH₃ and they may be flowed into the reaction space together. In some embodiments, the molybdenum precursor, and/or one or more of the reactants may be supplied with a carrier gas. In some embodiments, a co-flow of the second reactant and the third reactant may consist of CO, and H₂. In some embodiments, a co-flow of the second reactant and the third reactant may consist of CO, and NH₃.

In some embodiments, a MoC or Mo₂C film may be deposited. In some embodiment, the molybdenum precursor may comprise MoOCl₄ or MoO₂Cl₂, and the co-flow of the second reactant and the third reactant may comprise CO and H₂. The deposition of MoC, MoOC or Mo₂C may be controlled by tuning a ratio of the second reactant and the third reactant.

In some embodiments, a MoOCN, or MoCN film may be deposited. In some embodiment, the molybdenum precursor comprises MoOCl₄ or MoO₂Cl₂, and the co-flow of the second reactant and the third reactant may comprise CO and NH₃. In some embodiments the third reactant comprises NH₃ and H₂, such that CO, NH₃ and H₂ are flowed together.

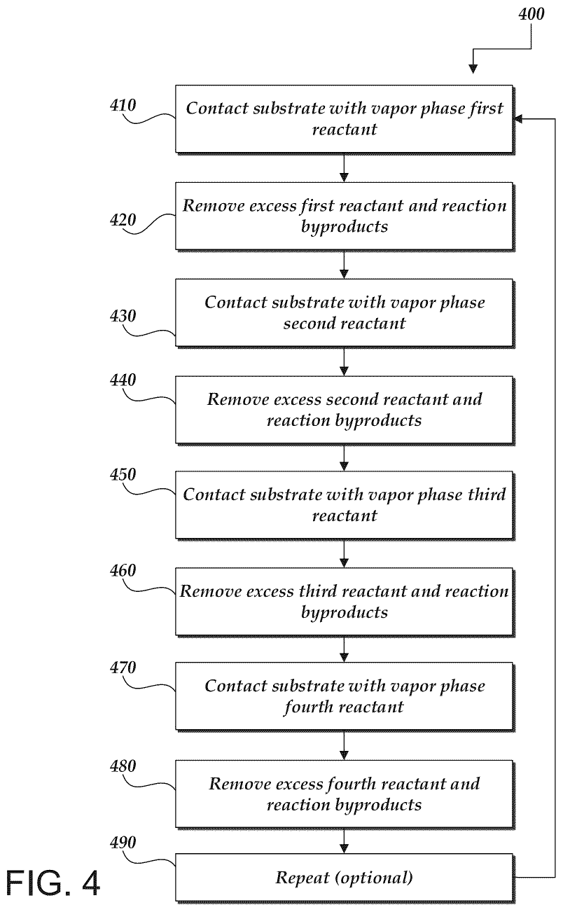

FIG. 4 is a flow-chart illustrating a deposition process 400 for depositing a thin film comprising molybdenum according to some embodiments. The deposition process 400 is similar to the deposition process 200 except that an additional fourth reactant is further used. The deposition process 400 comprises at least one deposition cycle comprising contacting the surface of the substrate with a first reactant comprising a vapor phase molybdenum precursor at block 410, removing any excess molybdenum precursor and reaction byproducts, if any, from the surface at block 420, contacting the surface of the substrate with a vapor phase second reactant at block 430, removing any excess second reactant and reaction byproducts, if any, from the surface of the substrate at block 440, contacting the surface of the substrate with a vapor phase third reactant at block 450, removing any excess third reactant and reaction byproducts, if any, from the surface of the substrate at block 460, contacting the surface of the substrate with a vapor phase fourth reactant at block 470, and removing any excess fourth reactant and reaction byproducts, if any, from the surface of the substrate at block 480. The contacting and removing steps can be repeated at block 490 to form the thin film comprising molybdenum of a desired thickness. For example, MoOCN or MoCN thin films can be deposited.

In some embodiments, the molybdenum precursor may comprise molybdenum halide or molybdenum oxyhalide. For example, the molybdenum precursor may comprise at least one of MoO₂Cl₂, MoCl₅, MoOCl₄, MoBr₂, or MoI₃.

In some embodiments, the second reactant may comprise a first reducing agent. In some embodiments, the second reactant may comprise carbon. In some embodiments the second reactant may comprise carbon and oxygen, such as carbon monoxide (CO), the third reactant may comprise nitrogen, such as ammonia (NH₃), and the fourth reactant may comprise a second reducing agent, such as hydrogen (H₂). In some embodiments, the second reactant may consist of carbon monoxide (CO), the third reactant may consist of ammonia (NH₃), and the fourth reactant may consist of hydrogen (H₂).

In some embodiments, the second reactant may comprise carbon and oxygen, such as carbon monoxide (CO), the third reactant may comprise hydrogen (H₂), and the fourth reactant may comprise nitrogen, such as ammonia (NH₃). In some embodiments, the second reactant may consist of carbon and oxygen, such as carbon monoxide (CO), the third reactant may consist of hydrogen (H₂), and the fourth reactant may consist of ammonia (NH₃).

In some embodiments, the second reactant may comprise hydrogen (H₂), the third reactant may comprise carbon and oxygen, such as carbon monoxide (CO), and the fourth reactant may comprise nitrogen, such as ammonia (NH₃). In some embodiments, the second reactant may consist of hydrogen (H₂), the third reactant may consist of carbon and oxygen, such as carbon monoxide (CO), and the fourth reactant may consist of nitrogen, such as ammonia (NH₃).

In some embodiments, the second reactant may comprise hydrogen (H₂), the third reactant may comprise nitrogen, such as ammonia (NH₃), and the fourth reactant may comprise carbon and oxygen, such as carbon monoxide (CO). In some embodiments, the second reactant may consist of hydrogen (H₂), the third reactant may consist of nitrogen, such as ammonia (NH₃), and the fourth reactant may consist of carbon and oxygen, such as carbon monoxide (CO).

In some embodiments, the second reactant may comprise nitrogen, such as ammonia (NH₃), the third reactant may comprise carbon and oxygen, such as carbon monoxide (CO), and the fourth reactant may comprise hydrogen (H₂). In some embodiments, the second reactant may consist of nitrogen, such as ammonia (NH₃), the third reactant may consist of carbon and oxygen, such as carbon monoxide (CO), and the fourth reactant may consist of hydrogen (H₂).

In some embodiments, the second reactant may comprise nitrogen, such as ammonia (NH₃), the third reactant may comprise hydrogen (H₂), and the fourth reactant may comprise carbon and oxygen, such as carbon monoxide (CO). In some embodiments, the second reactant may consist of nitrogen, such as ammonia (NH₃), the third reactant may consist of hydrogen (H₂), and the fourth reactant may consist of carbon and oxygen, such as carbon monoxide (CO).

In some embodiments, H₂ may be co-flowed with NH₃ in any of the deposition processes, for example at steps 200, 300, or 400 in FIGS. 2, 3 and 4 respectively.

In some embodiments, an oxidization process can be performed, for example prior to block 230. For example, in an oxidation process H₂O, O₃, H₂O₂, N₂O, NO₂ or NO may be contacted with the substrate. For example, a molybdenum precursor comprising MoOCl₄ can be dissociated in an oxidation step to form MoO₂ and release HCl gas and O₂. After the oxidation process, MoO₂ may be reduced to form Mo film using the second and/or the third reactant, i.e., CO and H₂ and/or NH₃. In some embodiments, the oxidation process can comprise co-flowing H₂O and H₂.

### Thin Film Characteristics

Thin films deposited according to some of the embodiments described herein may be continuous thin films comprising molybdenum. In some embodiments the thin films comprising molybdenum may be continuous at a thickness below about 100 nm, below about 60 nm, below about 50 nm, below about 40 nm, below about 30 nm, below about 25 nm, or below about 20 nm or below about 15 nm or below about 10 nm or below about 5 nm or lower. The continuity referred to can be physically continuity or electrical continuity. In some embodiments, the thickness at which a film may be physically continuous may not be the same as the thickness at which a film is electrically continuous, and the thickness at which a film may be electrically continuous may not be the same as the thickness at which a film is physically continuous.

While in some embodiments a thin film comprising molybdenum deposited according to some of the embodiments described herein may be continuous, in some embodiments it may be desirable to form a non-continuous thin film comprising molybdenum, or a thin film comprising separate islands or nanoparticles comprising molybdenum. In some embodiments the deposited thin film comprising molybdenum may comprise nanoparticles comprising molybdenum that are not substantially physically or electrically continuous with one another. In some embodiments the deposited thin film comprising molybdenum may comprise separate nanoparticles, or separate islands, comprising molybdenum.

In some embodiments a thin film comprising molybdenum deposited according to some of the embodiments described herein may have a resistivity of less than about 20 μΩcm at a thickness of less than about 100 nm. In some embodiments a thin film comprising molybdenum deposited according to some of the embodiments described herein may have a resistivity of less than about 20 μΩcm at a thickness of below about 60 nm, below about 50 nm, below about 40 nm, below about 30 nm, below about 25 nm, or below about 20 nm or lower. In some embodiments a thin film comprising molybdenum deposited according to some of the embodiments described herein may have a resistivity of less than about 15 μΩcm at a thickness of below about 60 nm, below about 50 nm, below about 40 nm, below about 30 nm, below about 25 nm, or below about 20 nm or lower. In some embodiments a thin film comprising molybdenum deposited according to some of the embodiments described herein may have a resistivity of less than about 10 μΩcm at a thickness of below about 60 nm, below about 50 nm, below about 40 nm, below about 30 nm, below about 25 nm, or below about 20 nm or lower. In some embodiments a thin film comprising molybdenum deposited according to some of the embodiments described herein may have a resistivity of less than about 200 μΩcm at a thickness of below about 30 nm, below about 20 nm, below about 15 nm, below about 10 nm, below about 8 nm, or below about 5 nm or lower.

In some embodiments a thin film comprising molybdenum deposited according to some of the embodiments described herein may have a resistivity of less than about 200 μΩcm, less than about 100 μΩcm, less than about 50 μΩcm, less than about 30 μΩcm, less than about 20 μΩcm less than about 18μΩcm, less than about 15 μΩcm, less than about 12 μΩcm less than about 10 μΩcm, less than about 8 μΩcm, or less than about 5 μΩcm or lower at a thickness of less than about 100 nm. In some embodiments a thin film comprising molybdenum deposited according to some of the embodiments described herein may have a resistivity of less than about 20 μΩcm, less than about 18 μΩcm, less than about 15 μΩcm, less than about 12 μΩcm, less than about 10 μΩcm, less than about 8 μΩcm, or less than about 5 μΩcm or lower at a thickness of less than about 50 nm.

In some embodiments an MoC, Mo₂C, MoOC, MoOCN, or MoCN film is deposited to a thickness of less than about 10 nm, more preferably less than about 5 nm and most preferably less than about 3 nm.

Atomic layer deposition allows for conformal deposition of Mo, MoC, Mo₂C, MoOC, MoOCN, or MoCN films. In some embodiments, the Mo, MoC, Mo₂C or MoCN films deposited by the processes disclosed herein on a three-dimensional structure have at least 90%, 95% or higher conformality. In some embodiments the films are about 100% conformal.

In some embodiments, the Mo, MoC, Mo₂C, MoOC, MoOCN, or MoCN film formed has step coverage of more than about 80%, more preferably more than about 90%, and most preferably more than about 95% in structures which have high aspect ratios. In some embodiments high aspect ratio structures have an aspect ratio that is more than about 3:1 when comparing the depth or height to the width of the feature. In some embodiments the structures have an aspect ratio of more than about 5:1, or even an aspect ratio of 10:1 or greater.

In some embodiments, the molybdenum films, such as Mo, MoC, Mo₂C, MoOC, MoOCN, or MoCN films deposited by processes disclosed herein are treated after the deposition, such as by annealing, as desired depending on the application. In some embodiments the Mo, MoC, Mo₂C, MoOC, MoOCN, or MoCN films are annealed in an oxygen environment. For example, the films may be annealed at an elevated temperature in water or O₂. In some embodiments an annealing step is not carried out.

In some embodiments, following deposition of the molybdenum films, such as Mo, MoC, Mo₂C or MoCN deposition, a further film is deposited. In some embodiments the additional film may be directly over and contacting the molybdenum film, such as directly over and contacting a Mo, MoC, Mo₂C, MoOC, MoOCN, or MoCN layer.

Although certain embodiments and examples have been discussed, it will be understood by those skilled in the art that the scope of the claims extend beyond the specifically disclosed embodiments to other alternative embodiments and/or uses and obvious modifications and equivalents thereof.

What is claimed is:

1. A process for forming a thin film comprising molybdenum on a substrate in a reaction space, the process comprising a deposition cycle comprising:
providing the substrate in the reaction space;
providing a vapor phase molybdenum precursor to the reaction space;
after providing the vapor phase molybdenum precursor, providing a second reactant comprising CO; and
after providing the second reactant, providing a third reactant comprising one or more of H₂ and NH₃.

2. The process of claim 1, wherein the second reactant comprises a reducing agent.

3. The process of claim 2, wherein the second reactant consists of CO.

4. The process of claim 1, wherein the molybdenum precursor comprises at least one of MoCl₅, MoBr₂, MoI₃, MoOCl₄, and MoO₂Cl₂.

5. The process of claim 1, wherein the third reactant comprises H₂.

6. The process of claim 5, wherein the deposition cycle further comprises providing a fourth reactant comprising NH₃.

7. The process of claim 1, wherein the only precursors and reactants provided in the deposition cycle are molybdenum halides, CO, and H₂.

8. The process of claim 1, wherein the only precursors and reactants provided in the deposition cycle are molybdenum halides, CO, H₂, and NH₃.

9. The process of claim 1, wherein the deposition cycle is repeated two or more times to form the thin film, wherein the thin film comprises one or more of Mo, MoC, Mo₂C, MoOC, MoOCN, or MoCN.

10. The process of claim 1, wherein the deposition cycle further comprises removing excess vapor phase molybdenum precursor and reaction byproducts, if any, from the reaction space after contacting the substrate with the molybdenum precursor and prior to providing the second reactant and providing the third reactant.

11. The process of claim 1, further comprising providing an oxygen reactant.

12. The process of claim 11, wherein the oxygen reactant comprises at least one of H₂O, O₃, H₂O₂, N₂O, NO₂ or NO.

13. A process for forming a thin film comprising molybdenum on a substrate in a reaction space, the process comprising:
providing the substrate in the reaction space;
performing a deposition cycle, the deposition cycle comprising:
contacting the substrate with a vapor phase molybdenum precursor to form adsorbed species on a surface of the substrate;
contacting the substrate with a second reactant comprising CO, wherein the second reactant reacts with the adsorbed species.

14. The process of claim 13, wherein the second reactant consists of CO.

15. The process of claim 13, wherein the deposition cycle further comprises contacting the substrate with a third reactant comprising one or more of H₂ and NH₃.

16. The process of claim 15, wherein the third reactant comprises H₂, and wherein the deposition cycle further comprises contacting the substrate with the third reactant comprising NH₃.

17. The process of claim 13, wherein the deposition cycle forms the thin film comprising molybdenum, wherein the thin film comprises of one or more of Mo, MoC, Mo₂C, MoOC, MoOCN, or MoCN.

18. The process of claim 13, wherein the molybdenum precursor comprises at least one of MoCl₅, MoBr₂, MoI₃, MoOCl₄, and MoO₂Cl₂.

19. The process of claim 13, wherein a temperature in the reaction space during the deposition cycle is between about 200° C. and about 700° C.

20. A process for forming a thin film on a substrate in a reaction space, the process comprising:
providing the substrate in the reaction space; and
performing a deposition cycle to form the thin film, wherein the deposition cycle comprises:
providing a vapor phase molybdenum precursor to the reaction space, and
providing a second reactant comprising CO,
wherein the thin film consists essentially of one or more of MoC, Mo₂C, MoOC, MoOCN, or MoCN.
